(19) United States
(12) Patent Application Publication
(10) Pub. No.: US 2012/0100686 A1
(43) Pub. Date: Apr. 26, 2012

(54) METHOD OF FORMING ULTRA-SHALLOW JUNCTIONS IN SEMICONDUCTOR DEVICES

(75) Inventors: Wei-Yuan LU, Taipei City (TW); Li-Ping HUANG, Taipei City (TW); Mao-Rong YEH, Tao yuan City (TW); Chun-Feng NIEH, Hsinchu City (TW)

(73) Assignee: TAIWAN SEMICONDUCTOR MANUFACTURING COMPANY, LTD., Hsinchu (TW)

(21) Appl. No.: 12/908,640

(22) Filed: Oct. 20, 2010

(51) Int. Cl. H01L 21/336

(52) U.S. Cl. 438/303; 438/299; 438/301; 257/E21.409

(57) ABSTRACT

A method of forming ultra-shallow lightly doped source/drain (LDD) regions of a CMOS transistor in a surface of a substrate includes the steps of providing a semiconductor substrate, providing a gate stack on the semiconductor substrate, performing a low temperature pocket implantation process on the substrate, performing a low temperature co-implanted ion implantation process on the substrate, and/or performing a low temperature lightly doped source/drain implantation process on the substrate.

### CROSS REFERENCE

The present disclosure is related to the following commonly-assigned U.S. patent application, the entire disclosure of which is incorporated herein by reference: U.S. application Ser. No. 12/713,356 for “METHOD OF FORMING ULTRA-SHALLOW JUNCTIONS IN SEMICONDUCTOR DEVICES” (attorney docket No. TSMC 2009-0567).

### FIELD OF THE INVENTION

This invention is related generally to semiconductor devices, and more particularly to the formation of MOS devices with ultra-shallow junctions.

### BACKGROUND OF THE INVENTION

As the dimensions of transistors are scaled down, the reduction of vertical junction depth and the suppression of dopant lateral diffusion, in order to control short-channel effects, become greater challenges. MOS devices have become so small that the diffusion of impurities from lightly doped source/drain (LDD) regions and source/drain regions will significantly affect the characteristics of the MOS devices. Particularly, impurities from LDD regions are readily diffused into the channel region, causing short channel effects and leakage currents between the source and drain regions.

Typically, when LDD regions are formed in a semiconductor substrate by ion implantation, the junction depth is not just dependent on the ion implant energy but can also depend on channeling phenomena such as transient enhanced diffusion (TED) when the implanted ions migrate through the crystal lattice during subsequent thermal processing. Current techniques for forming ultra-shallow doped regions, such as p-type LDD (PLDD) regions in PMOS devices and n-type LDD (NLDD) regions in NMOS devices, use pre-amorphization techniques to amorphize the semiconductor substrate (i.e., turn a portion of the crystalline silicon substrate into amorphous silicon) by, for example, ion implantation using non-electrically active ions, such as silicon, germanium and fluorine, in order to eliminate channeling. The pre-amorphization implantation creates in the substrate an amorphous surface layer adjacent to the underlying crystalline semiconductor material and produces a large number of defects beyond the amorphous/crystalline interface. These crystal defects are usually called End of Range (EOR) defects. Defects of this kind are known to enhance diffusion of previously implanted dopant ions during subsequent thermal processes of annealing and activation of the semiconductor device.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flow chart of a method of fabricating a semiconductor device having ultra-shallow junctions according to various aspects of the present disclosure; and

FIGS. 2A-2I are cross-sectional views of an embodiment of a semiconductor device at various stages of fabrication according to the method of FIG. 1.

### DETAILED DESCRIPTION

It is understood that the following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

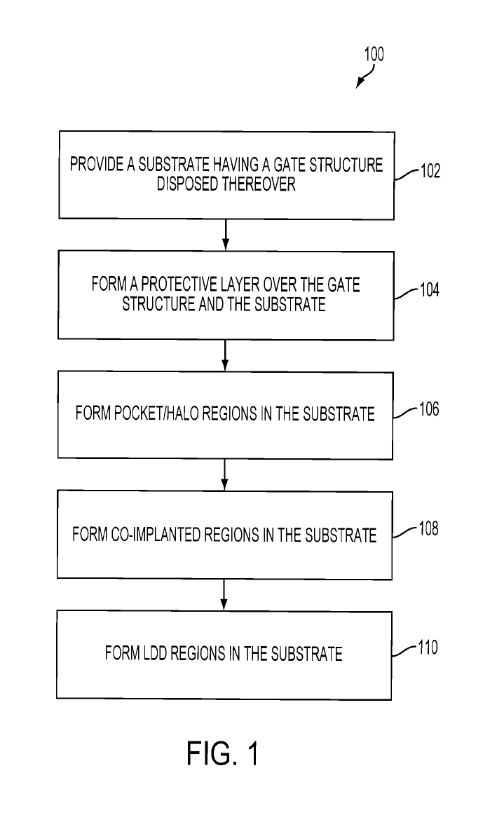

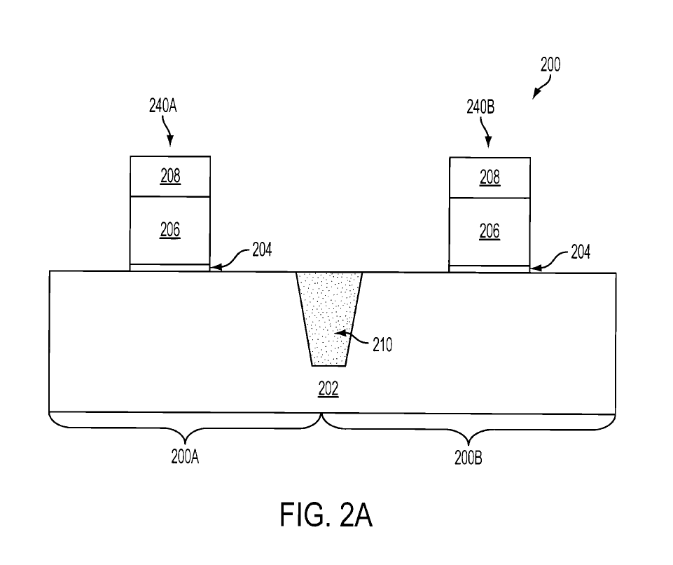

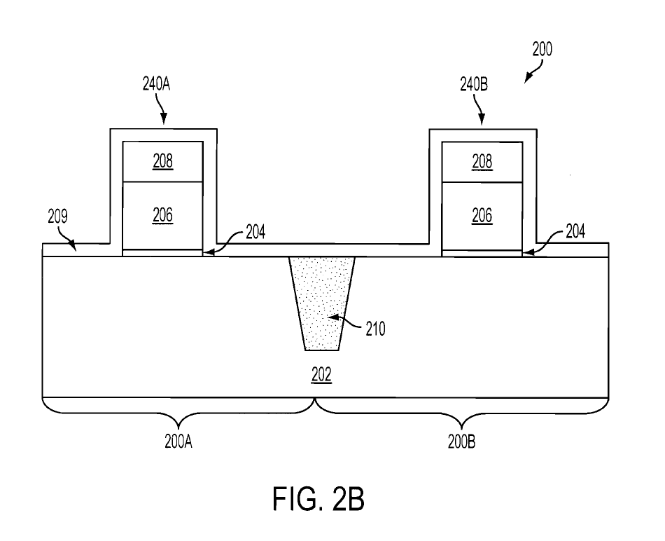

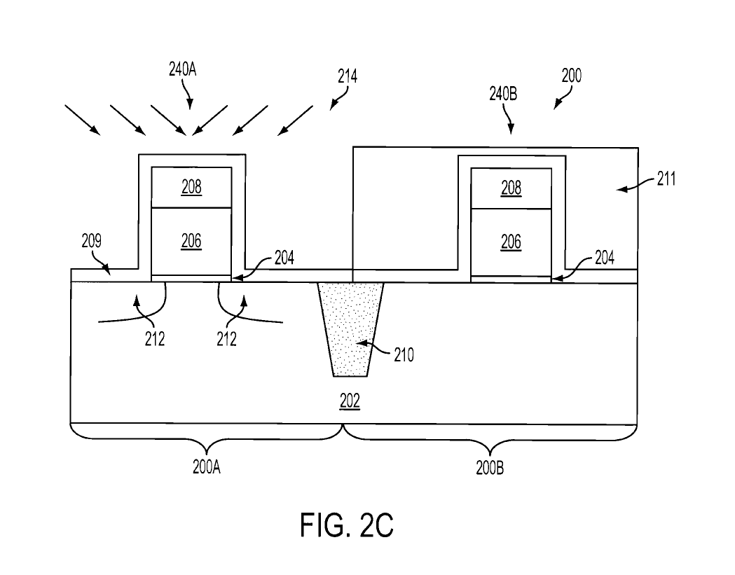

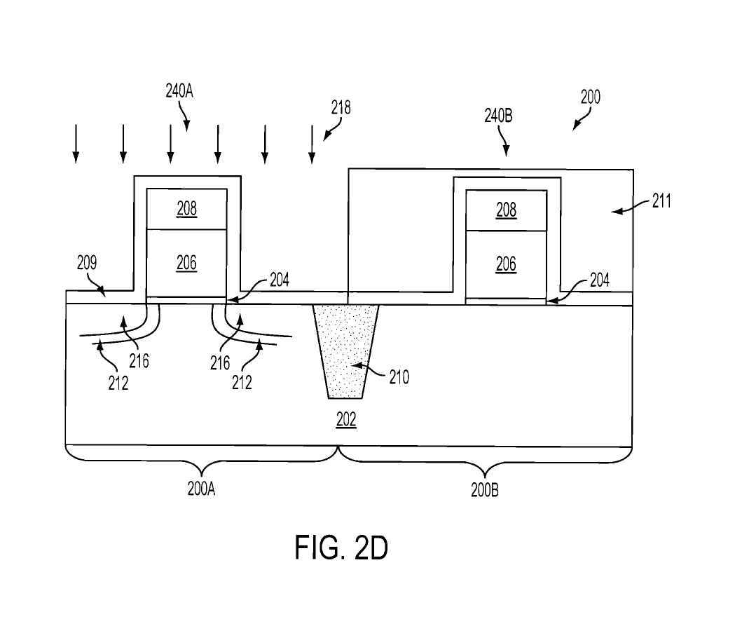

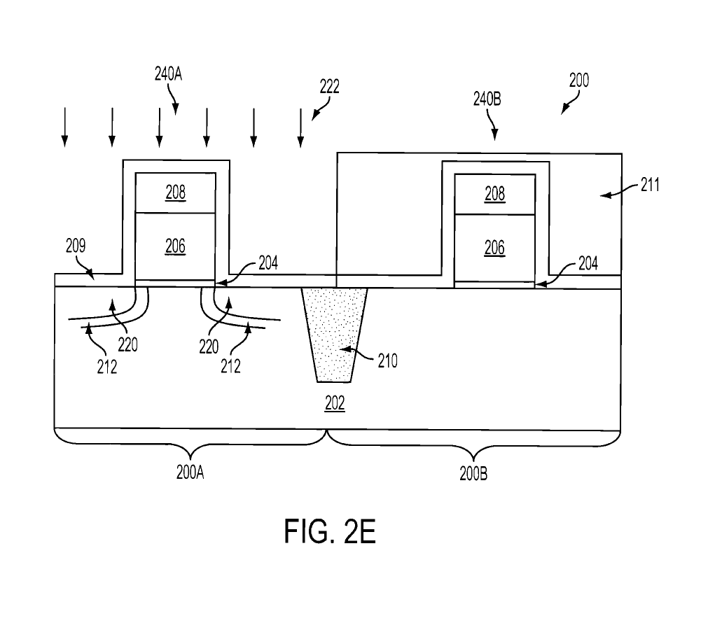

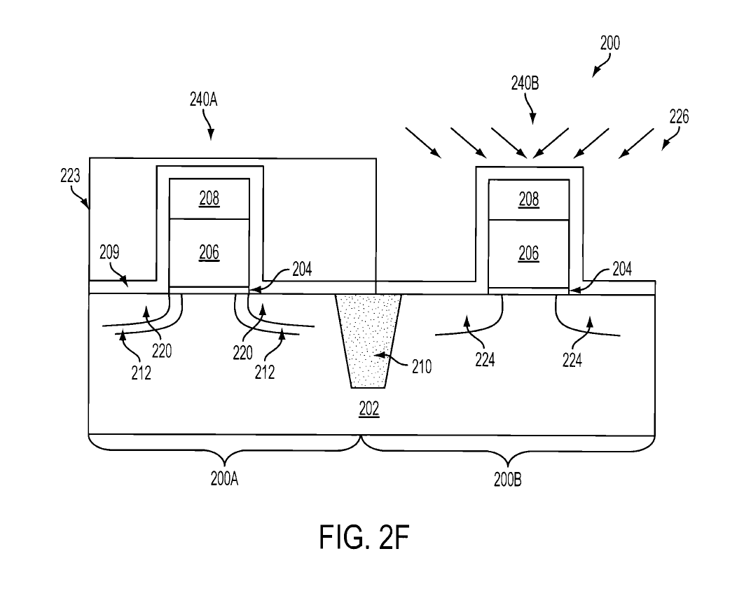

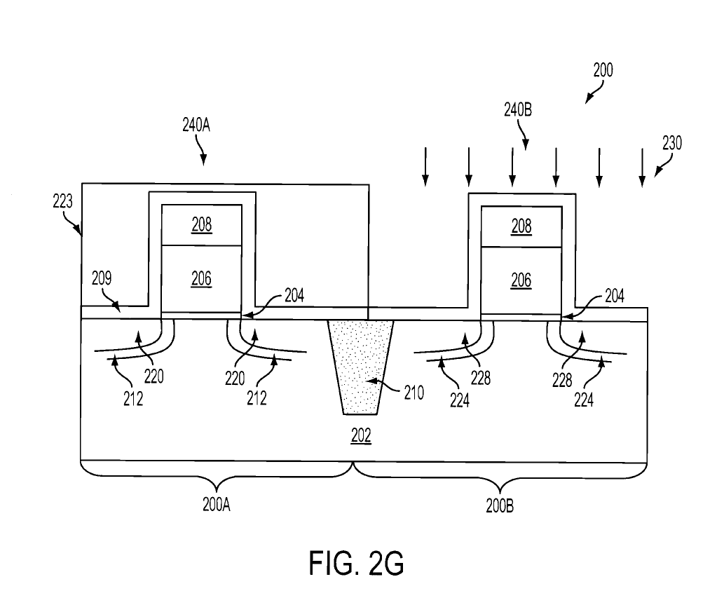

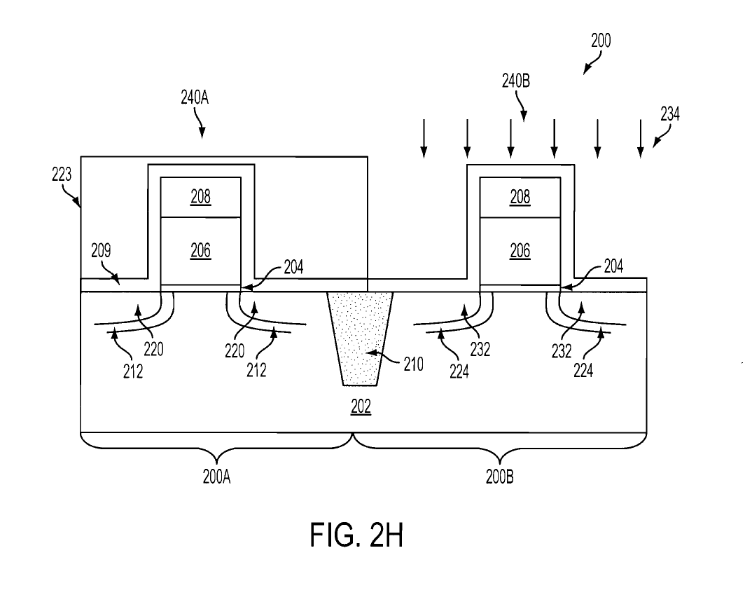

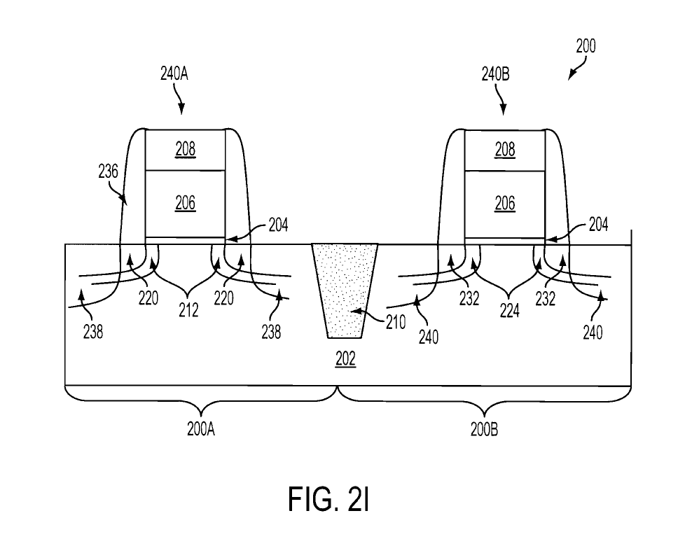

With reference to FIGS. 1 and 2A-2I, a method 100 and a semiconductor device 200 are collectively described below. The semiconductor device 200 illustrates an integrated circuit, or portion thereof, that can comprise memory cells and/or logic circuits. The semiconductor device 200 can include passive components such as resistors, capacitors, inductors, and/or fuses; and active components, such as P-channel field effect transistors (PFETs), N-channel field effect transistors (NFETs), metal-oxide-semiconductor field effect transistors (MOSFETs), complementary metal-oxide-semiconductor (CMOS) transistors, high voltage transistors, and/or high frequency transistors, other suitable components, and/or combinations thereof. It is understood that additional steps can be provided before, during, and/or after the method 100, and some of the steps described below can be replaced or eliminated, for additional embodiments of the method. It is further understood that additional features can be added in the semiconductor device 200, and some of the features described below can be replaced or eliminated, for additional embodiments of the semiconductor device 200.

Referring to FIGS. 1 and 2A, the method 100 begins at step 102 wherein a substrate 202 is provided. In the present embodiment, the substrate 202 is a semiconductor substrate comprising silicon. Alternatively, the substrate 202 comprises an elementary semiconductor including silicon and/or germanium in crystal; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The alloy semiconductor substrate may have a gradient SiGe feature in which the Si and Ge composition change from one ratio at one location to another ratio at another location of the gradient SiGe feature. The alloy SiGe may be formed over a silicon substrate. The SiGe substrate may be strained. Furthermore, the semiconductor substrate may be a semiconductor on insulator (SOI). In some examples, the semiconductor substrate may include a doped epi layer. In other examples, the silicon substrate may include a multilayer compound semiconductor structure.

The substrate 202 may include various doped regions depending on design requirements (e.g., p-type wells or n-type wells). The doped regions may be doped with p-type dopants, such as boron or BF₂; n-type dopants, such as phosphorus or arsenic; or a combination thereof. The doped regions may be formed directly in the substrate 202, in a P-well structure, in an N-well structure, in a dual-well structure, or using a raised structure. The semiconductor device 200 includes a NFET device 200A and a PFET device 200B, and thus, the substrate 202 may include various doped regions configured for a particular device in each of the NFET device 200A and the PFET device 200B. A gate structure 240A for the NFET device 200A and a gate structure 240B for the PFET device 200B are formed over the substrate 202. In some embodiments, the gate structures 240A and 240B include, in order, a gate dielectric 204, a gate electrode 206, and a hard mask 208. The gate structures 240A and 240B may be formed by deposition, lithography patterning, and etching processes.

The gate dielectric 204 is formed over the substrate 202 and includes a dielectric material, such as silicon oxide, silicon oxynitride, silicon nitride, a high-k dielectric material, other suitable dielectric material, or combinations thereof. Exemplary high-k dielectric materials include HfO₂, HfSiO, HfSiON, HfTaO, HfTiO, HfZrO, other suitable materials, or combinations thereof. The gate dielectric 204 may be a multilayer structure, for example, including an interfacial layer, and a high-k dielectric material layer formed on the interfacial layer. An exemplary interfacial layer may be a grown silicon oxide layer formed by a thermal process or atomic layer deposition (ALD) process.

The gate electrode 206 is formed over the gate dielectric 204. In some embodiments, the gate electrode 206 is a polycrystalline silicon (polysilicon) layer. The polysilicon layer may be doped for proper conductivity. Alternatively, the polysilicon is not necessarily doped if a dummy gate is to be formed and replaced in a subsequent gate replacement process. Alternatively, the gate electrode 206 could include a conductive layer having a proper work function, therefore, the gate electrode 206 can also be referred to as a work function layer. The work function layer comprises any suitable material, such that the layer can be tuned to have a proper work function for enhanced performance of the associated device. For example, if a p-type work function metal (p-metal) for the PFET device is desired, TiN or TaN may be used. On the other hand, if an n-type work function metal (n-metal) for the NFET device is desired, Ta, TiAl, TiAlN, or TaCN, may be used. The work function layer may include doped conducting oxide materials. The gate electrode layer 206 may include other conductive materials, such as aluminum, copper, tungsten, metal alloys, metal silicide, other suitable materials, or combinations thereof. For example, where the gate electrode 206 includes a work function layer, another conductive layer can be formed over the work function layer.

The hard mask 208 formed over the gate electrode 206 includes silicon oxide, silicon nitride, silicon oxynitride, silicon carbide, other suitable dielectric material, or combinations thereof. The hard mask 208 may have a multi-layer structure.

An isolation feature 210 is formed in the substrate 202 to isolate various regions of the substrate 202, such as the NFET device 200A and the PFET device 200B. The isolation feature 210 utilizes isolation technology, such as local oxidation of silicon (LOCOS) and/or shallow trench isolation (STI), to define and electrically isolate the various regions. The isolation feature 210 comprises silicon oxide, silicon nitride, silicon oxynitride, other suitable materials, or combinations thereof. The isolation feature 210 may be formed by any suitable process. As one example, forming an STI includes etching a trench in the substrate, filling the trench with one or more dielectric materials, and using chemical mechanical polishing (CMP) processing to form a planarized surface.

Referring to FIGS. 1 and 2B, the method 100 continues with step 104 in which a protective layer 209 may be formed over the substrate 202 and the gate structures 240A, 240B. The protective layer 209 acts as a protector to protect surface of the substrate 202 from damage during subsequent implantation processes. In one embodiment, the protective layer 209 is a dielectric layer. In another embodiment, the protective layer 209 is oxide material, e.g., silicon oxide or silicon oxynitride; or nitride material, e.g., silicon nitride. In some embodiments, the protective layer 209 has a thickness ranging between about 10 Angstroms and about 100 Angstroms.

Referring to FIGS. 1 and 2C, the method 100 continues with step 106 in which pocket/halo regions 212 are formed in the substrate 202 for the NFET device 200A, interposed by the gate structure 240A. The pocket/halo regions 212 may be partially under edges of the gate structure 240A. In one embodiment, the pocket/halo regions 212 are formed by a doping process 214, including an ion implantation process, a diffusion process, another suitable process, or combinations thereof. In another embodiments, the doping process 214 is a halo implantation process performed by, for example, a tilt implant process at a tilt angle ranging between about 0 degrees and about 60 degrees. In one embodiment, the doping process 214 is a halo implantation process performed with an energy ranging between about 10 KeV and about 100 KeV. In another embodiment, the doping process 214 is a halo implantation process performed with a dopant dosage ranging between about 1E13 atoms/cm² and about 1E15 atoms/cm².

In one embodiment, the doping process 214 is a halo implantation process performed on the substrate 202 with a temperature less than room temperature (room temperature being about 20° C. to 25° C.). In another embodiment, the doping process 214 is a halo implantation process performed on the substrate 202 with a temperature ranging between about 0° C. and about −100° C. In other embodiments, the doping process 214 is a halo implantation process performed on the substrate 202 with a temperature ranging between about −60° C. and about −100° C. The ion implantation process performed at a low temperature may decrease the damage of the substrate caused by the dosage implanted therein. In some embodiments, the doping process 214 is performed using an ion implanter adapting a Cryo (low temperature) function therein.

In some embodiments, more than one implantation may be conducted to form pocket/halo regions 212 in desired regions. In one embodiment, the pocket/halo regions 212 are doped with p-type dopant, such as boron or BF₂. In another embodiment, the pocket/halo regions are located around the side borders and junction of the subsequently formed source/drain regions (including LDD regions) to neutralize the diffusion of the n-type impurities. The PFET device 200B may be protected by a protector 211, such as a photoresist pattern or hard mask pattern, to prevent dopant from being implanted therein during the doping process 214 and/or subsequent implantation processes for forming doping regions in the NFET device 200A.

Referring to FIGS. 1 and 2D, the method 100 continues with step 108 in which co-implanted regions 216 are formed in the NFET device 200A, interposed by the gate structure 240A. In one embodiment, the co-implanted regions 216 are substantially aligned with the edges of the gate structure 240A. In another embodiment, each of the co-implanted regions 216 is located in each of the pocket/halo regions 212. In some embodiments, the co-implanted regions 216 are formed by a co-implanted implantation process 218. The co-implanted ion implantation process 218 introduces dopants, such as nitrogen and/or fluorine, to result in a trapping layer (not shown) in the substrate 202 to prevent interstitial back flow in the NFET device 200A.

In one embodiment, the co-implanted implantation process 218 is performed by an implant process at a tilt angle ranging between about 0 degrees and about 60 degrees. In another embodiment, the co-implanted implantation process 218 is performed at energy ranging between about 1 KeV and about 20 KeV. In other embodiments, the co-implanted implantation process 218 is performed with a dopant dosage ranging between about 5E14 atoms/cm² and about 2E15 atoms/cm². The co-implanted implantation process 218, for example, is conducted at a low temperature to form amorphous regions (not shown) in the co-implanted regions 216. In one embodiment, the co-implanted implantation process 218 is performed on the substrate 202 with a temperature less than room temperature. In another embodiment, the co-implanted implantation process 218 is performed on the substrate 202 with a temperature ranging between about 0° C. and about −100° C. In other embodiments, the co-implanted ion implantation process 218 is performed on the substrate 202 with a temperature ranging between about −60° C. and about −100° C. In some embodiments, the co-implanted implantation process 218 is performed using an ion implanter adapting a Cryo (low temperature) function therein.

The co-implanted implantation process 218 on the substrate 202 with a low temperature may form a thicker amorphous layer in the upper portion of the substrate 202 and decrease the transient enhanced diffusion (TED) phenomena in the lower portion of the substrate 202. Hence, ultra-shallow junctions in the NFET device 200A can be achieved by using the low temperature halo implantation process and/or the low temperature co-implanted implantation process

In addition, a pre-amorphization implantation process for forming an amorphous layer could be omitted because a thick amorphous layer can be formed by the low temperature halo implantation process and/or the low temperature co-implanted implantation process. Therefore, adapting the low temperature ion implantation process may simplify the process flow for forming the MOS device, and the defects caused by the step of pre-amorphization implantation could be prevented and the device performance is enhanced.

Referring to FIGS. 1 and 2E, the method 100 continues with step 110 in which lightly doped source/drain (LDD) regions 220 are formed for the NFET device 200A, interposed by the gate structure 240A. The LDD regions 220 are substantially aligned with the boundaries of the co-implanted regions 216. In some embodiments, the LDD regions 220 for the NFET device (NLDD) are doped with an n-type dopant by a doping process 222, such as phosphorous or arsenic. Hence, the LDD regions 220 may comprise a first dopant (such as nitrogen and/or fluorine) introduced by the co-implanted ion implantation process 218 and a second dopant (such as phosphorous or arsenic) introduced by the doping process 222.

In one embodiment, the doping process 222 comprises ion implantation process, diffusion process, other suitable process, or combinations thereof. In another embodiments, the doping process 222 is an ion implantation process performed by, for example, a tilt implant process at a tilt angle ranging between about 0 degrees and about 30 degrees. In one embodiment, the LDD implantation process 222 is performed at using an energy ranging between about 1 KeV and about 10 KeV. In another embodiment, the LDD implantation process 222 is performed with a dopant dosage ranging between about 5E14 atoms/cm² and about 2E15 atoms/cm².

In one embodiment, the LDD implantation process 222 is performed on the substrate 202 with a temperature less than room temperature. In another embodiment, the ion implantation process 222 is performed on the substrate 202 with a temperature ranging between about 0° C. and about −100° C. In other embodiments, the LDD implantation process 222 is performed on the substrate 202 with a temperature ranging between about −60° C. and about −100° C. In some embodiments, the LDD implantation process 222 is performed using an ion implanter adapting a Cryo (low temperature) function therein.

The LDD implantation process 222 performed at a low temperature may decrease the damage to the substrate caused by the dosage implanted therein and decrease the TED issue. Hence, ion species of phosphorus dimer, arsenic dimer, or the combination thereof may be used for the LDD implantation process 222.

Nitrogen and/or fluorine, introduced by the co-implanted ion implantation process 218, have the function of retarding the diffusion of other dopants. Therefore, the diffusion of the dopants introduced by the LDD implantation process 222 may be controlled when the semiconductor device 200 is annealed, and thus the NLDD regions 220 may have higher impurity concentrations within confined profiles for forming the ultra-shallow junction.

The protector 211 is thereafter removed by a photoresist stripping process, for example. In one embodiment, an anneal process may be performed on the substrate 202, after the stripping process, to repair the crystalline structure of the substrate 202 damaged by the doping process 214, the co-implanted implantation process 218, and/or the doping process 222. The anneal process, for example, is performed with a nitrogen ambient under a temperature ranging between about 900° C. and about 1100° C.

FIGS. 2F-2I illustrate ion implantation processes for the PFET device 200B. Referring to FIG. 2F, pocket/halo regions 224 are formed in the substrate 202, interposed by the gate structure 240B. The pocket/halo regions 224 may be partially under edges of the gate structure 240B. In one embodiment, the pocket/halo regions 224 are formed by a doping process 226, including ion implantation process, diffusion process, other suitable process, or combinations thereof. In other embodiments, the doping process 226 is an halo implantation process performed by, for example, a tilt implant process at a tilt angle ranging between about 0 degrees and about 60 degrees. In one embodiment, the doping process 226 is a halo implantation process performed with an energy ranging between about 10 KeV and about 100 KeV. In another embodiment, the doping process 226 is a halo implantation process performed with a dopant dosage ranging between about 1E13 atoms/cm² and about 1E15 atoms/cm².

In one embodiment, the doping process 226 is a halo implantation process performed on the substrate 202 with a temperature less than room temperature. In another embodiment, the doping process 226 is a halo implantation process performed on the substrate 202 with a temperature ranging between about 0° C. and about −100° C. In other embodiments, the doping process 226 is a halo implantation process performed on the substrate 202 with a temperature ranging between about −60° C. and about −100° C. The ion implantation process performed at a low temperature may decrease the damage of the substrate caused by the dosage implanted therein. In some embodiments, the doping process 226 is performed using an ion implanter adapting a Cryo (low temperature) function therein.

In some embodiments, more than one implantation may be conducted to form pocket/halo regions 224 in desired regions. In one embodiment, the pocket/halo regions 224 are doped with n-type dopant, such as phosphor or arsenic. In another embodiment, the pocket/halo regions 224 are located around the side borders and junction of the subsequently formed source/drain regions (including LDD regions) to neutralize the diffusion of the p-type impurities. The NFET device 200A may be protected by a protector 223, such as a photoresist pattern or hard mask pattern, to prevent dopant implanted therein during the doping process 226 and/or subsequent implantation process for forming doping regions in the PFET device 200B.

Referring to FIG. 2G, co-implanted regions 228 are formed in the PFET device 200B, interposed by the gate structure 240B. In one embodiment, the co-implanted regions 228 are substantially aligned with the edges of the gate structure 240B. In another embodiment, each of the co-implanted regions 228 is located in each of the pocket/halo regions 224. In some embodiments, the co-implanted regions 228 are formed by a co-implanted implantation process 230. The co-implanted ion implantation process 230 introduces dopants, such as nitrogen and/or fluorine, to result in a trapping layer (not shown) in the substrate 202 to prevent interstitial back flow in the PFET device 200B.

In one embodiment, the co-implanted implantation process 230 is performed by an implantation process at a tilt angle ranging between about 0 degrees and about 60 degrees. In another embodiment, the co-implanted implantation process 230 is performed at energy ranging between about 1 KeV and about 20 KeV. In other embodiments, the co-implanted implantation process 230 is performed with a dopant dosage ranging between about 5E14 atoms/cm² and about 2E15 atoms/cm². The co-implanted implantation process 230, for example, is conducted at a low temperature to form amorphous regions (not shown) in the co-implanted regions 228. In one embodiment, the co-implanted implantation process 230 is performed on the substrate 202 with a temperature less than room temperature. In another embodiment, the co-implanted implantation process 230 is performed on the substrate 202 with a temperature ranging between about 0° C. and about −100° C. In other embodiments, the co-implanted ion implantation process 230 is performed on the substrate 202 with a temperature ranging between about −60° C. and about −100° C. In some embodiments, the co-implanted implantation process 230 is performed using an ion implanter adapting a Cryo (low temperature) function therein.

The co-implanted implantation process 230 on the substrate 202 with a low temperature may form a thicker amorphous layer in the upper portion of the substrate 202 and decrease the transient enhanced diffusion (TED) phenomena in the lower portion of the substrate 202. Hence, ultra-shallow junctions in the PFET device 200B can be achieved by using the low temperature halo implantation process and/or the low temperature co-implanted implantation process

In addition, a pre-amorphization implantation process for forming amorphous layer could be omitted because a thick amorphous layer can be formed by the low temperature halo implantation process and/or the low temperature co-implanted implantation process. Therefore, adapting the low temperature ion implantation process may simplify the process flow for forming the MOS device, and the defects caused by the step of pre-amorphization implantation could be prevented and the device performance is enhanced.

Referring to FIG. 2H, lightly doped source/drain (LDD) regions 232 are formed for the PFET device 200B, interposed by the gate structure 240B. The LDD regions 232 are substantially aligned with the boundaries of the co-implanted regions 228. In some embodiments, the LDD regions 232 for the PFET device (PLDD) are doped with a p-type dopant by a doping process 234, such as boron or BF₂. Hence, the LDD regions 232 may comprise a first dopant (such as nitrogen and/or fluorine) introduced by the co-implanted ion implantation process 230 and a second dopant (such as boron) introduced by the doping process 234.

In one embodiment, the doping process 234 comprises an ion implantation process, a diffusion process, another suitable process, or combinations thereof. In other embodiments, the doping process 234 is an ion implantation process performed by, for example, a tilt implant process at a tilt angle ranging between about 0 degrees and about 30 degrees. In one embodiment, the LDD implantation process 234 is performed using an energy ranging between about 1 KeV and about 10 KeV. In another embodiment, the LDD implantation process 234 is performed with a dopant dosage ranging between about 5E14 atoms/cm² and about 2E15 atoms/cm².

In one embodiment, the LDD implantation process 234 is performed on the substrate 202 with a temperature less than room temperature. In another embodiment, the ion implantation process 234 is performed on the substrate 202 with a temperature ranging between about 0° C. and about −100° C. In other embodiments, the LDD implantation process 234 is performed on the substrate 202 with a temperature ranging between about −60° C. and about −100° C. In some embodiments, the LDD implantation process 234 is performed using an ion implanter adapting a Cryo (low temperature) function therein.

The LDD implantation process 234 performed at a low temperature may decrease the damage of the substrate caused by the dosage implanted therein and decrease the TED issue. Hence, ion species of boron dimer may be used for the LDD implantation process 234.

Nitrogen and/or fluorine, introduced by the co-implanted ion implantation process 230, have the function of retarding the diffusion of other dopants. Therefore, the diffusion of the dopants introduced by the LDD implantation process 234 may be controlled when the semiconductor device 200 is annealed, and thus the PLDD regions 232 may have higher impurity concentrations within confined profiles for forming the ultra-shallow junction.

The protector 223 is thereafter removed by a photoresist stripping process, for example. In one embodiment, an anneal process may be performed on the substrate 202, after the stripping process, to repair the crystalline structure of the substrate 202 damaged by the doping process 226, the co-implanted implantation process 230, and/or the doping process 234. The anneal process, for example, is performed with a nitrogen ambient under a temperature ranging between about 900° C. and about 1100° C.

Spacers 236 are then formed as shown in FIG. 2I. Thereafter, source/drain (S/D) regions 238, 240 may be formed in the substrate 202 by implantation processes. One or more thermal processes, such as rapid thermal anneal (RTA), may also be performed on the substrate 202 to activate the dopants in the S/D regions.

Subsequent processing may implement a gate replacement process. For example, metal gates may replace the gate structures 240A, 240B (i.e., polysilicon gate layer) of the NFET/PFET devices 200A/200B. A first metal gate having a first work function may be formed in the gate structure 240A and a second gate structure having a second work function may be formed in the gate structure 240B. The metal gates may comprise any suitable material including aluminum, copper, tungsten, titanium, tantalum, tantalum aluminum, tantalum aluminum nitride, titanium nitride, tantalum nitride, nickel silicide, cobalt silicide, silver, TaC, TaSiN, TaCN, TiAl, TiAlN, WN, metal alloys, other suitable materials, and/or combinations thereof.

Although the invention has been described in terms of exemplary embodiments, it is not limited thereto. Rather, the appended claims should be construed broadly to include other variants and embodiments of the invention that may be made by those skilled in the art without departing from the scope and range of equivalents of the invention.

1. A method comprising:
providing a substrate;
performing a pocket implantation process on the substrate, wherein the pocket implantation process is performed utilizing a first temperature less than room temperature;
performing a co-implanted ion implantation process on the substrate, wherein the co-implanted ion implantation process is performed utilizing a second temperature; and
performing a lightly doped source/drain implantation process on the substrate to implant dimers, wherein the lightly doped source/drain implantation process is performed utilizing a third temperature less than room temperature.

2. The method of claim 1, wherein there is not a step of pre-amorphization implantation performed before or after the steps of pocket implantation or lightly doped source/drain implantation.

3. The method of claim 1, wherein the first, the second, or the third temperature is ranging between about 0° C. and about −100° C.

4. The method of claim 1, wherein the first, the second, or the third temperature is ranging between about −60° C. and about −100° C.

5. The method of claim 1, wherein the second temperature is less than room temperature.

6. The method of claim 1, wherein performing the co-implanted ion implantation process includes implanting the substrate with ion species of nitrogen, fluorine, carbon, or combinations thereof.

7. The method of claim 1, wherein performing the lightly doped source/drain implantation includes implanting the substrate with ion species of phosphorus dimer, arsenic dimer, or a combination thereof.

8. The method of claim 1, further comprising a step of, after the step of lightly doped source/drain implantation, forming spacers adjacent to a gate stack on the substrate and providing source/drain implantation into the substrate.

9. The method of claim 1, wherein the pocket implantation process, the co-implanted ion implantation process, or the lightly doped source/drain implantation process is performed using an ion implanter with a Cryo function.

10. A method of forming MOS transistors comprising:
providing a gate stack on a substrate;
providing a protective layer over the gate stack and the substrate;
performing a pocket implantation process on the substrate, wherein the pocket implantation process is performed at a temperature between about 0° C. and about −100° C.;
performing a co-implanted ion implantation process on the substrate; performing a lightly doped source/drain implantation process on the substrate, wherein the lightly doped source/drain implantation process is performed at a temperature between about 0° C. and about −100° C.; and
after the pocket implantation process, the co-implanted ion implantation process, and the lightly doped source/drain implantation process, forming a spacer on a sidewall of the gate stack.

11. The method of claim 10, wherein there is not a step of pre-amorphization implantation process performed before or after the steps of pocket implantation or lightly doped source/drain implantation.

12. The method of claim 10, wherein the co-implanted ion implantation process is performed at a temperature less than room temperature.

13. (canceled)

14. The method of claim 10, wherein the pocket implantation process, the co-implanted ion implantation process, or the lightly doped source/drain implantation process is performed at a temperature ranging between about −60° C. and about −100° C.

15. The method of claim 10, wherein performing the co-implanted ion implantation process includes implanting the substrate with implant species of nitrogen, fluorine, carbon, or combinations thereof.

16. The method of claim 10, further comprising a step of, after the step of lightly doped source/drain implantation, forming spacers adjacent to the gate stack and providing source/drain implantation into the substrate.

17. The method of claim 10, wherein the co-implanted ion implantation process is performed by an ion implanter with a Cryo function.

18. The method of claim 10, further comprising:
performing an anneal process on the substrate after the pocket implantation process, the co-implanted ion implantation process, or the lightly doped source/drain implantation process.

19. The method of claim 18, wherein the anneal process is performed under a nitrogen ambient with a temperature ranging between about 900° C. and about 1100° C.

20. The method of claim 10, wherein performing the lightly doped source/drain implantation includes implanting the substrate with ion species of phosphorus dimer, arsenic dimer, or the combination thereof.

21. (canceled)

22. A method of forming MOS transistors comprising:
forming a gate stack on a substrate;
forming a protective layer over the gate stack and the substrate;
performing a pocket implantation process on the substrate, wherein the pocket implantation process is performed at a temperature lower than a room temperature;
performing a co-implanted ion implantation process on the substrate; and
performing a lightly doped source/drain implantation process on the substrate, wherein the lightly doped source/drain implantation process is performed at a temperature lower than the room temperature, and wherein no pre-amorphization is performed between the step of forming the gate stack and before either one of the steps of the pocket implantation process and the lightly doped source/drain implantation process.
